(19) United States
(12) Patent Application Publication
(10) Pub. No.: US 2026/0107592 A1
(43) Pub. Date: Apr. 16, 2026

(54) IMAGE SENSOR PACKAGE AND METHOD OF MANUFACTURING THE SAME

(71) Applicant: SAMSUNG ELECTRONICS CO., LTD., SUWON-SI (KR)

(72) Inventor: Sanguk KIM, Suwon-si (KR)

(73) Assignee: SAMSUNG ELECTRONICS CO., LTD., SUWON-SI (KR)

(21) Appl. No.: 19/294,965

(22) Filed: Aug. 8, 2025

(30) Foreign Application Priority Data
Oct. 14, 2024 (KR) 10-2024-0139729

(51) Int. Cl. H10F 39/00

(52) U.S. Cl. CPC H10F 39/804; H10F 39/014

(57) ABSTRACT

An image sensor package includes a package substrate, an image sensor chip disposed on the package substrate and including a chip body, a sensing region disposed in an central region of the chip body, and a chip pad disposed in an edge region of the chip body, a bonding wire connecting the image sensor chip to the package substrate, a dam structure disposed at an edge of the image sensor chip, a glass cover disposed on the dam structure, and a sealant covering the glass cover and the bonding wire, and the dam structure is disposed on the chip pad and includes a die adhesive layer in contact with the chip pad, a glue layer in contact with the glass cover, and an intermediate relief layer disposed between the die adhesive layer and the glue layer.

### CROSS-REFERENCE TO RELATED APPLICATION

This application is based on and claims priority under 35 U.S.C. §119 to Korean Patent Application No. 10-2024-0139729, filed on October 14, 2024, in the Korean Intellectual Property Office, the disclosure of which is incorporated by reference herein in its entirety.

### BACKGROUND

The inventive concept relates to an image sensor, and more particularly, to an image sensor package and a method of manufacturing the same.

The image sensor package as a core component mounted on a camera device is used in a wide variety of fields, including vehicles and portable terminals such as a mobile phone or a tablet, beyond a scope of a common camera. The image sensor package may have various package structures such as a chip on board (COB), a chip on flexible PCB (COF), a chip on glass (COG), a wafer level chip scale package (WLCSP), an image sensor ball grid array (IBGA), and a plastic leadless chip carrier (PLCC). On the other hand, the image sensor package having an IBGA structure, which is widely applied to vehicles, may be formed by settling an image sensor on a package substrate and bonding a glass cover onto the image sensor.

### SUMMARY

The inventive concept relates to an image sensor package with improved reliability and a method of manufacturing the same.

According to an aspect of the inventive concept, there is provided an image sensor package including a package substrate, an image sensor chip disposed on a central region of the package substrate and including a chip body, a sensing region disposed in an upper central region of the chip body, and a chip pad disposed in an upper edge region of the chip body, a bonding wire electrically connecting the image sensor chip to the package substrate and contacting the chip pad, a dam structure disposed at an edge of the image sensor chip and overlapping the chip pad and one end of the bonding wire in contact with the chip pad in a vertical direction, a glass cover disposed on the dam structure, and a sealant covering side surfaces of the glass cover and the bonding wire. The dam structure is disposed on the chip pad and includes a die adhesive layer in contact with the chip pad, a glue layer in contact with the glass cover, and an intermediate relief layer disposed between the die adhesive layer and the glue layer.

According to another aspect of the inventive concept, there is provided an image sensor package including a package substrate including a substrate base, an upper substrate pad disposed on a top surface of the substrate base, and a lower substrate pad disposed on a bottom surface of the substrate base, an external connection terminal disposed on the lower substrate pad, an image sensor chip disposed on a central region of the package substrate and including a chip body, a sensing region disposed in an upper central region of the chip body, and a chip pad disposed in an upper edge region of the chip body, a bonding wire electrically connecting the image sensor chip to the package substrate and contacting the upper substrate pad and the chip pad, a dam structure disposed at an edge of the image sensor chip and overlapping the chip pad and one end of the bonding wire in contact with the chip pad in a vertical direction, a glass cover disposed on the dam structure, and a sealant covering side surfaces of the glass cover and the bonding wire. The dam structure is disposed on the chip pad and includes a die adhesive layer in contact with the chip pad, a glue layer in contact with the glass cover, and an intermediate relief layer disposed between the die adhesive layer and the glue layer.

According to another aspect of the inventive concept, there is provided a method of manufacturing an image sensor package, including preparing a package substrate, forming an adhesive layer on a central region of the package substrate and mounting an image sensor chip, which includes a chip body and a chip pad, on the adhesive layer, forming a bonding wire connecting an upper substrate pad of the package substrate to the chip pad of the image sensor chip, forming an intermediate relief layer on a top surface of a die adhesive layer and attaching the die adhesive layer with the intermediate relief layer formed on a top surface of the die adhesive layer to an edge region of the image sensor chip, forming a glue layer on the intermediate relief layer to form a dam structure, attaching a glass cover onto the dam structure, sealing the image sensor chip and forming a sealant covering side surfaces of the glass cover and the bonding wire, and forming an external connection terminal on a bottom substrate pad of the package substrate.

### BRIEF DESCRIPTION OF THE DRAWINGS

Embodiments will be more clearly understood from the following detailed description taken in conjunction with the accompanying drawings in which:

FIG. 1 is a cross-sectional view illustrating an image sensor package according to embodiments;

FIG. 2 is an enlarged cross-sectional view of the portion EX1 of FIG. 1; and

FIG. 3, FIG. 4, FIG. 5, FIG. 6, FIG. 7, FIG. 8, FIG. 9, FIG. 10 and FIG. 11 are views for describing a method of manufacturing an image sensor package, according to embodiments.

### DETAILED DESCRIPTION OF THE EMBODIMENTS

Hereinafter, embodiments of the inventive concept will be described in detail with reference to the accompanying drawings. Like reference numerals refer to like elements throughout and description thereof will not be given.

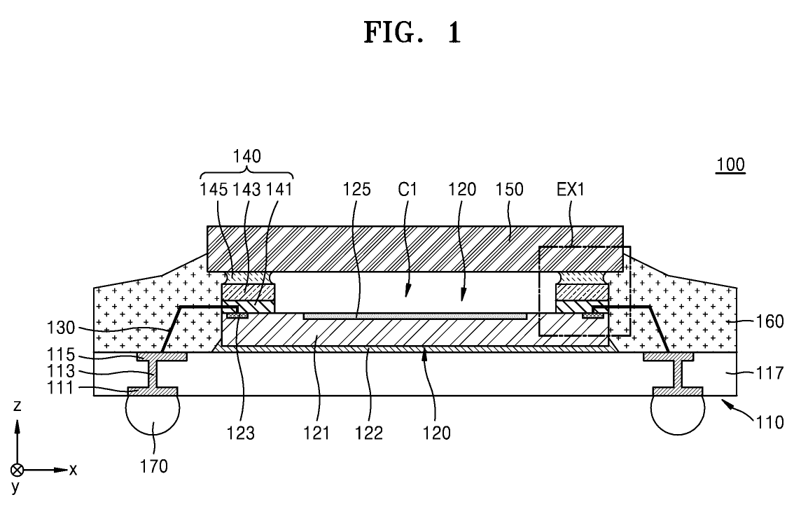

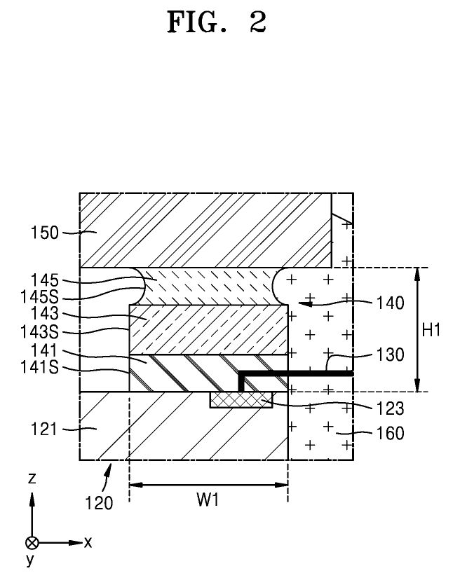

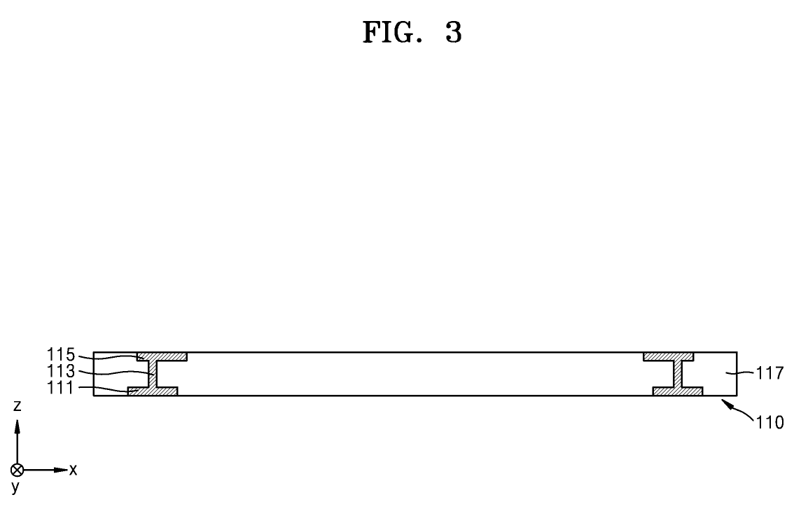

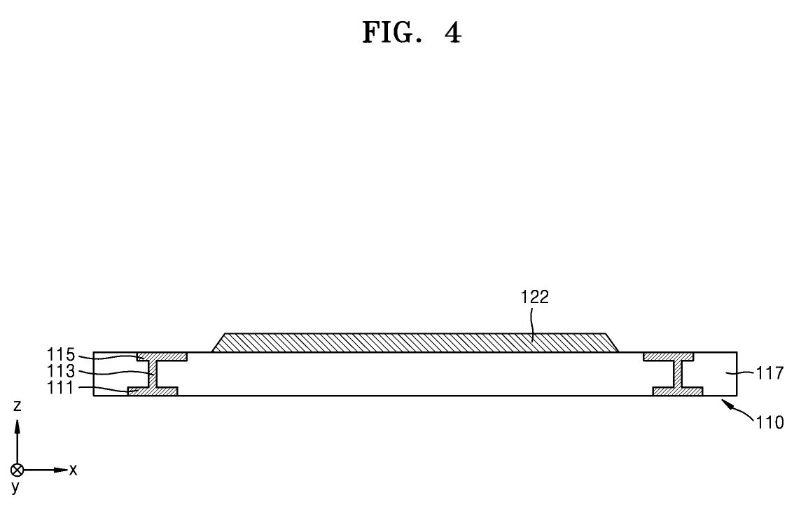

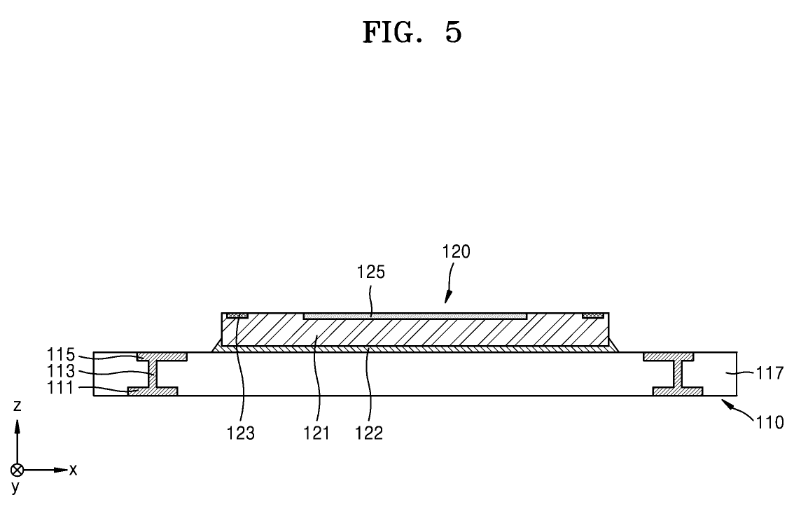

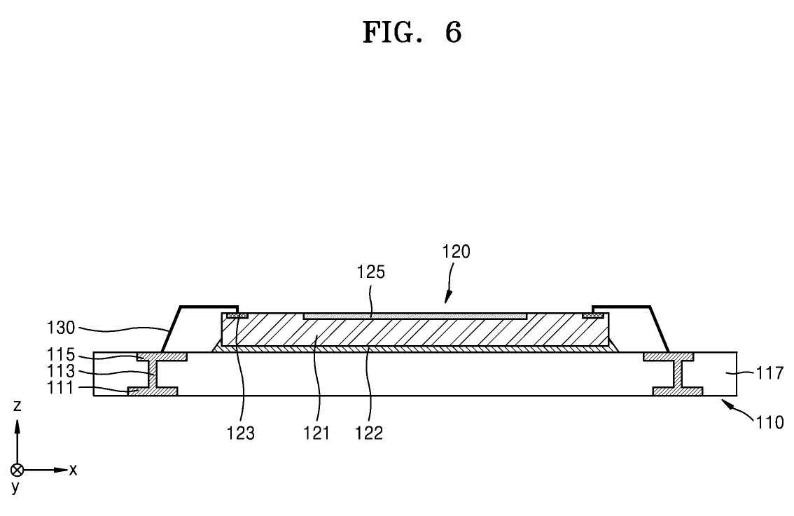

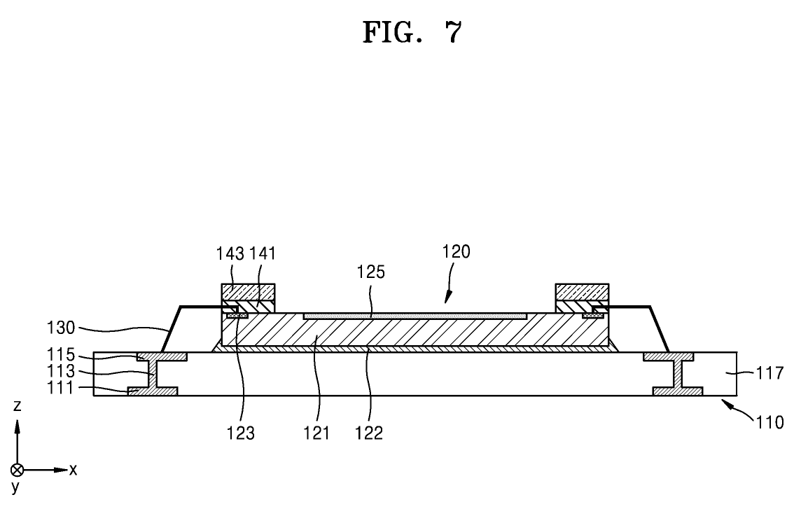

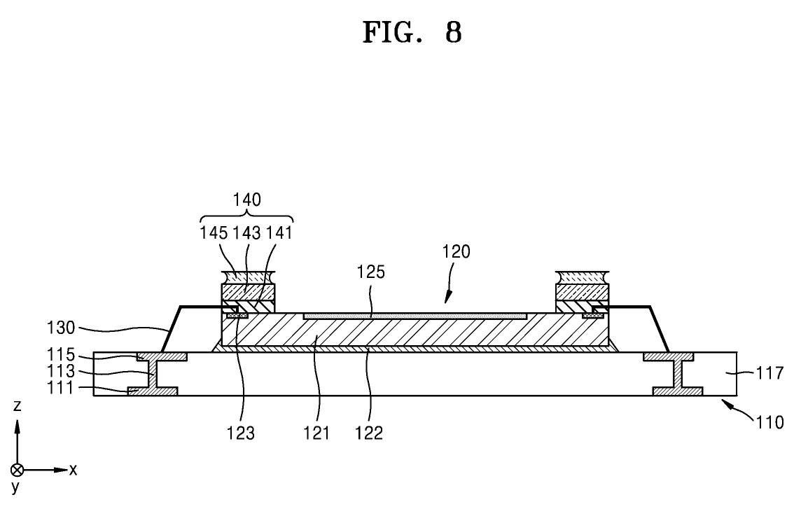

FIG. 1 is a cross-sectional view illustrating an image sensor package 100 according to embodiments. FIG. 2 is an enlarged cross-sectional view of the portion EX1 of FIG. 1.

Referring to FIGS. 1 and 2, the image sensor package 100 may include a package substrate 110, an image sensor chip 120, bonding wires 130, a dam structure 140, a glass cover 150, and a sealant 160.

The package substrate 110 may have a rectangular shape in a plan view. Side surfaces of the sealant 160 disposed on the package substrate 110 may be limited by side surfaces of the package substrate 110. Therefore, in general, the planar size of the image sensor package 100 may be determined by the size of the package substrate 110.

The package substrate 110 may include lower substrate pads 111, wiring layers 113, upper substrate pads 115, and a substrate base 117. The lower substrate pads 111 may be disposed on a bottom surface of the package substrate 110, that is, a bottom surface of the substrate base 117. The upper substrate pads 115 may be disposed on a top surface of the package substrate 110, that is, a top surface of the substrate base 117. The upper substrate pads 115 may be disposed along both side surfaces of the image sensor chip 120 mounted on the package substrate 110. The upper substrate pads 115 may be electrically connected to corresponding chip pads 123 of the image sensor chip 120 through the bonding wires 130.

The lower substrate pads 111 and the upper substrate pads 115 may be disposed at an outer portion of the package substrate 110. For example, each of the lower substrate pads 111 and the upper substrate pads 115 may be disposed in one or more rows in a first horizontal direction (X direction) or a second horizontal direction (Y direction) in the outer portion of the package substrate 110.

At least parts of the lower substrate pads 111 may overlap at least parts of the upper substrate pads 115 in a vertical direction (Z direction).

The wiring layers 113 may be disposed in the substrate base 117. Although it is illustrated in FIG. 1 that the wiring layers 113 each in a single layer are disposed in the substrate base 117, the inventive concept is not limited thereto. For example, the wiring layers 113 each in a multi-layer may be disposed in the substrate base 117. The wiring layers 113 may be connected to the lower substrate pads 111 and the upper substrate pads 115, respectively. The lower substrate pads 111 may be electrically connected to the upper substrate pads 115 by the wiring layers 113, respectively.

The lower substrate pads 111, the wiring layers 113, and the upper substrate pads 115 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru) or a combination thereof.

The substrate base 117 occupies most of the package substrate 110 and may configure an external shape of the package substrate 110. The substrate base 117 may include various materials. For example, depending on a type of the package substrate 110, the substrate base 117 may include silicon, ceramic, an organic material, glass, and epoxy resin. For example, the package substrate 110 may be a printed circuit board (PCB) including the substrate base 117 including epoxy resin. However, the package substrate 110 according to the inventive concept is not limited to the PCB.

Although it is illustrated in FIGS. 1 and 2 that side surfaces of the upper substrate pads 115 and side surfaces of the lower substrate pads 111 are surrounded by the substrate base 117, the inventive concept is not limited thereto. For example, the upper substrate pads 115 may be disposed on the top surface of the substrate base 117 and may protrude from the top surface of the substrate base 117, and the lower substrate pads 111 may be disposed on the bottom surface of the substrate base 117 and may protrude from the bottom surface of the substrate base 117. In this case, the package substrate 110 may further include an upper passivation layer (not shown) covering the top surface of the substrate base 117 and exposing the upper substrate pads 115 and a lower passivation layer (not shown) covering the bottom surface of the substrate base 117 and exposing the lower substrate pads 111.

External connection terminals 170 may be disposed on the lower substrate pads 115, respectively. The external connection terminals 170 may be connected to the lower substrate pads 115, respectively. The external connection terminals 170 may be, for example, solder balls. The image sensor package 100 according to embodiments may be mounted on an external device such as a camera device through the external connection terminals 170.

The image sensor chip 120 may be mounted on a central region of the package substrate 110. In embodiments, the image sensor chip 120 may be mounted on the package substrate 110 in a wire bonding structure. The image sensor chip 120 may include, for example, a CMOS image sensor (CIS) and a charge-coupled device (CCD). An active surface of the image sensor chip 120 may face the glass cover 150 above and an inactive surface of the image sensor chip 120 may face the package substrate 110 below.

An adhesive layer 122 may be between the image sensor chip 120 and the package substrate 110. The adhesive layer 122 may attach the image sensor chip 120 onto the package substrate 110, and may alleviate shock applied to the image sensor chip 120 included in the image sensor package 100 when external shock is applied to the image sensor package 100.

The image sensor chip 120 may include a chip body 121, chip pads 123, and a sensing region 125. The chip body 121 may include a substrate and a wiring layer of the image sensor chip 120. The substrate of the chip body 121 may include, for example, a silicon bulk wafer or an epitaxial wafer. The epitaxial wafer may include a crystalline material layer grown by an epitaxial process on a bulk substrate, that is, an epitaxial layer. However, the substrate is not limited to a bulk wafer or an epitaxial wafer, and may include various wafers such as a polished wafer, an annealed wafer, and a silicon on insulator (SOI) wafer. The wiring layer may be formed on either side of the substrate. For example, the wiring layer may be disposed under the sensing region 125.

The sensing region 125 may correspond to an upper central region of the chip body 121. The sensing region 125 may include a pixel region including a plurality of pixels. The pixel region may be referred to as an active pixel sensor (APS) region. The plurality of pixels constituting the pixel region may be disposed in a two-dimensional array structure. In addition, each of the plurality of pixels of the pixel region may include a photodiode (PD) formed in the substrate. The PD may be formed through an ion implantation process in which impurity ions are implanted into the pixel region. Each of the plurality of pixels of the pixel region may absorb incident light to generate and accumulate charges corresponding to an amount of light, and may transmit the accumulated charges to the outside through a pixel transistor. For example, the pixel transistor may include a transfer transistor, a source follower transistor, a reset transistor, and a selection transistor. The pixel region PI may be disposed in a central portion of the image sensor chip 120 in a plan view.

A plurality of color filters and a plurality of micro-lenses may be disposed on the sensing region 125 of the image sensor chip 120. The plurality of color filters may include a red (R) filter, a blue (B) filter, and a green (G) filter. Alternatively, the plurality of color filters may include a cyan (C) filter, a yellow (Y) filter, and a magenta (M) filter. The plurality of micro-lenses may condense light incident on the sensing region 125 into each of the plurality of pixels. Each of the plurality of pixels may recognize one color by detecting separate components of incident light.

The chip pads 123 may be disposed at an edge region of the image sensor chip 120. The edge region may refer to an outer portion of the image sensor chip 120 surrounding the sensing region 125. The chip pads 123 may be horizontally apart from the sensing region 125 of the image sensor chip 120. The chip pads 123 may be disposed in the first horizontal direction (X direction) or the second horizontal direction (Y direction) at an outer portion of the edge region. The chip pads 123 may be electrically connected to the wiring layer of the image sensor chip 120.

The chip pads 123 may be electrically connected to the upper substrate pads 115 of the package substrate 110 through the bonding wires 130, respectively. For example, one end of each of the bonding wires 130 may be connected to each of the chip pads 123, and the other ends of the bonding wires 130 may be connected to the upper substrate pads 115, respectively. The bonding wires 130 may include, for example, gold (Au), Cu, silver (Ag), Al, or a combination thereof. In embodiments, the bonding wires 130 may be connected by either a thermo-compression connection method or an ultrasonic connection method, or by a thermo-sonic connection method obtained by combining the thermo-compression connection method with the ultrasonic connection method.

The dam structure 140 may be disposed on an outer portion of a top surface of the image sensor chip 120. The dam structure 140 may have a rectangular ring shape surrounding the outer portion of the top surface of the image sensor chip 120 in a plan view. The dam structure 140 may cover the chip pads 123 of the image sensor chip 120. Accordingly, the dam structure 140 may cover one end portion of the bonding wire 130 connected to the chip pad 123 together.

As the dam structure 140 is disposed on the outer portion of the image sensor chip 120, an external surface of the dam structure 140 may be disposed on substantially the same plane as the side surfaces of the image sensor chip 120.

The dam structure 140 may be apart from the sensing region 125 of the image sensor chip 120 by a predetermined distance in a plan view. The dam structure 140 may have a vertical length H1 of about 50 μm to about 250 μm. When the dam structure 140 is formed directly on the chip body 121 of the image sensor chip 120 by a dispensing method using a liquid material, the vertical length H1 of the dam structure 140 is limited due to the liquid dispensing method. However, in the case of the dam structure 140 of the image sensor package 100 according to an embodiment, the die adhesive layer 141 and the intermediate relief layer 143 included in the dam structure 140 are not formed directly on the chip body 121 of the image sensor chip 120 and are disposed on the chip body 121 in a manner in which the die adhesive layer 141 is prepared, the intermediate relief layer 143 is formed on the die adhesive layer 141, and then the die adhesive layer 141 with the intermediate relief layer 143 formed on the top surface of the die adhesive layer 141 is attached onto the chip body 121. Accordingly, the vertical length H1 of the dam structure 140 may be easily controlled as needed.

The dam structure 140 may include a die adhesive layer 141, an intermediate relief layer 143, and a glue layer 145. The die adhesive layer 141 may be disposed on the chip pads 123 of the image sensor chip 120. The die adhesive layer 141 may overlap the chip pads 123 and one end of each of the bonding wires 130 connected to the chip pads 123 in the vertical direction (Z direction). The die adhesive layer 141 may cover the chip pads 123 and one end of each of the bonding wires 130 connected to the chip pads 123. The die adhesive layer 141 may be in contact with the chip pads 123, one end of each of the bonding wires 130 connected to the chip pads 123, and part of a top surface of the chip body 121. In embodiments, the die adhesive layer 141 may include a material having higher viscosity than the intermediate relief layer 143. For example, when the intermediate relief layer 143 includes a silicon-based material, the die adhesive layer 141 may include epoxy resin having higher viscosity than the silicon-based material. In embodiments, the die adhesive layer 141 may include a solid die attach film.

The intermediate relief layer 143 may be disposed on the die adhesive layer 141. The intermediate relief layer 143 may be apart from the image sensor chip 120 in the vertical direction (Z direction) with the die adhesive layer 141 therebetween. That is, the intermediate relief layer 143 may not be in direct contact with the image sensor chip 120.

In a process of forming the dam structure 140 to be described below, after the intermediate relief layer 143 is formed on the die adhesive layer 141, the die adhesive layer 141 with the intermediate relief layer 143 formed on a top surface of the die adhesive layer 141 may be attached onto the chip body 121 of the image sensor chip 120. That is, the intermediate relief layer 143 may not be formed directly on the chip body 121. Accordingly, a bleeding phenomenon of materials forming the intermediate relief layer 143, which may occur when the intermediate relief layer 143 is formed directly on the chip body 121, may be prevented so that it is possible to prevent the sensing region 125 of the image sensor chip 120 from being contaminated due to the bleeding phenomenon.

In addition, the conventional dam structure formed by dispensing a liquid material directly on the chip body 121 must be formed on the chip body 121 of the image sensor chip 120 to ensure a certain distance or more from the sensing region 125 of the image sensor chip 120 in consideration of the above-described bleeding phenomenon. However, in the case of the dam structure 140 according to the inventive concept, because the die adhesive layer 141 of the dam structure 140 is attached onto the chip body 121 as described above, the bleeding phenomenon is prevented so that the dam structure 140 may be disposed to have a less distance from the sensing region 125 than the conventional dam structure. As a result, the dam structure 140 according to the inventive concept may have a greater horizontal width than the conventional dam structure described above based on the image sensor chip 120 of the same area so that it is possible to obtain a higher effect of reducing a difference in coefficient of thermal expansion (CTE) between the glue layer 145 and the chip body 121 by the dam structure 140. In addition, the dam structure 140 according to embodiments may be less apart from the sensing region 125 so that even the image sensor chip 120 with a relatively small area may have a sufficient horizontal width to secure the effect of reducing the difference in CTE between the glue layer 145 and the chip body 121.

The intermediate relief layer 143 may include a material capable of reducing the difference in CTE between the glue layer 145 and the chip body 121 of the image sensor chip 120. The intermediate relief layer 143 may include, for example, a metal material such as Si or Cu.

When the die adhesive layer 141 and the intermediate relief layer 143 are omitted, in other words, when the dam structure 140 includes only the glue layer 145, the glue layer 145 is in direct contact with the image sensor chip 120. In this case, due to the difference in CTE between the glue layer 145 and the chip body 121 of the image sensor chip 120, a lower layer of the glue layer 145 adjacent to the chip body 121 may be stressed during a process of manufacturing the image sensor package 100 so that cracks may occur in the lower layer of the glue layer 145 or peeling of the lower layer may occur. As a result, reliability of the image sensor package 100 may deteriorate.

On the other hand, when the dam structure 140 includes the intermediate relief layer 143 between the glue layer 145 and the chip body 121, because the difference in CTE between the glue layer 145 and the chip body 121 of the image sensor chip 120 may be reduced by the intermediate relief layer 143, it is possible to prevent the reliability of the image sensor package 100 described above from deteriorating.

The glue layer 145 may be disposed on the intermediate relief layer 143. The glue layer 145 may be in contact with a top surface of the intermediate relief layer 143 on a bottom surface of the glue layer 145, and may be in contact with a bottom surface of the glass cover 150 on a top surface of the glue layer 145. The glue layer 145 may include, for example, glass attach glue including epoxy resin. However, the inventive concept is not limited thereto. Intermediate portions of side surfaces 145S of the glue layer 145 may be concave inward the image sensor package. The shape of the side surfaces 145S of the glue layer 145 may be due to the formation of the glue layer 145 by dispensing liquid epoxy resin constituting the glue layer 145 onto the intermediate relief layer 143 in the process of manufacturing the image sensor package 100.

In embodiments, side surfaces 141S of the die adhesive layer 141 and side surfaces 143S of the intermediate relief layer 143 may be disposed on substantially the same plane in the vertical direction of the image sensor package. The side surfaces 141S of the die adhesive layer 141 and the side surfaces 143S of the intermediate relief layer 143 may be flat surfaces in the vertical direction of the image sensor package. On the other hand, the intermediate portions of the side surfaces 145S of the glue layer 145 may be concave inward the image sensor package as described above, and may not be disposed on the same plane as the side surfaces 141S of the die adhesive layer 141 and the side surfaces 143S of the intermediate relief layer 143.

In embodiments, the die adhesive layer 141 and the intermediate relief layer 143 may have the same width W1 in a horizontal direction of the image sensor package. The width W1 may be, for example, about 100 μm to about 300 μm. The width W1 may be the same as a horizontal width of the dam structure 140.

The glass cover 150 may be disposed above the image sensor chip 120. The glass cover 150 may be disposed on the dam structure 140 formed on the top surface of the image sensor chip 120. That is, the glass cover 150 may be apart from the top surface of the image sensor chip 120 by a height of the dam structure 140. A cavity C1, which is an empty space, may be provided between the glass cover 150 and the image sensor chip 120. The cavity C1 may be sealed by the dam structure 140. Accordingly, moisture or foreign substances from the outside may be prevented from penetrating the cavity C1. The glass cover 150 may include, for example, transparent glass, transparent resin, or transparent ceramic.

In embodiments, a size of the glass cover 150 may be greater than a size of the image sensor chip 120. For example, a length of the glass cover 150 in the first horizontal direction (X direction) may be greater than a length of the image sensor chip 120 in the first horizontal direction (X direction). In this case, side surfaces of the glass cover 150 may be disposed outside the side surfaces of the image sensor chip 120 and the external surface of the dam structure 140. In other embodiments, the size of the glass cover 150 may be less than the size of the image sensor chip 120. In this case, the side surfaces of the glass cover 150 may be disposed inside the side surfaces of the image sensor chip 120 and the external surface of the dam structure 140.

The sealant 160 may be disposed on the package substrate 110 and may seal the image sensor chip 120, the bonding wires 130, and the glass cover 150. Specifically, the sealant 160 may cover the side surfaces of the image sensor chip 120 and the glass cover 150 from the top surface of the package substrate 110. In addition, the sealant 160 may cover the bonding wires 130 and may cover the external surface of the dam structure 140. The sealant 160 together with the dam structure 140 may prevent the sensing region 125 of the image sensor chip 120 from being contaminated by external foreign substances. In addition, the sealant 160 may protect the image sensor package 100 from external shock.

The sealant 160 may surround at least parts of the side surfaces of the glass cover 150, and a top surface of the sealant 160 may have a slight inclination from a top surface of the glass cover 150. The sealant 160 may include, for example, an epoxy molding compound (EMC). However, the inventive concept is not limited thereto.

The image sensor package 100 according to embodiments includes the dam structure 140 between the glass cover 150 and the image sensor chip 120, and the dam structure 140 may include the die adhesive layer 141, the intermediate relief layer 143, and the glue layer 145 sequentially disposed in an outer region of the chip body 121 of the image sensor chip 120. Because the dam structure 140 includes the intermediate relief layer 143 between the glue layer 145 and the chip body 121, cracking or peeling of the lower layer of the glue layer 145, which may occur when the glue layer 145 and the chip body 121 are in direct contact, may be prevented. As a result, reliability of the image sensor package 100 may be improved.

In addition, in a process of manufacturing the image sensor package 100 to be described below, the intermediate relief layer 143 is not formed directly on the chip body 121 and is formed on the die adhesive layer 141 and the die adhesive layer 141 with the intermediate relief layer 143 formed on the top surface of the die adhesive layer 141 is attached onto the chip body 121. Accordingly, the bleeding phenomenon of the intermediate relief layer 143, which may occur when the intermediate relief layer 143 is formed directly on the chip body 121, may be prevented. As a result, it is possible to prevent the sensing region 125 of the image sensor chip 120 from being contaminated.

In addition, the conventional dam structure formed by dispensing a liquid material directly on the chip body 121 must be formed on the chip body 121 of the image sensor chip 120 to ensure a certain distance or more from the sensing region 125 of the image sensor chip 120 in consideration of the above-described bleeding phenomenon. However, in the case of the dam structure 140 according to the inventive concept, because the die adhesive layer 141 of the dam structure 140 is attached onto the chip body 121 as described above, the bleeding phenomenon is prevented so that the dam structure 140 may be disposed to have a less distance from the sensing region 125 than the conventional dam structure. As a result, the dam structure 140 according to the inventive concept may have a greater horizontal width than the conventional dam structure described above based on the image sensor chip 120 of the same area so that it is possible to obtain a higher effect of reducing a difference in CTE between the glue layer 145 and the chip body 121 by the dam structure 140. In addition, the dam structure 140 according to embodiments may be less apart from the sensing region 125 so that even the image sensor chip 120 with a relatively small area may have a sufficient horizontal width to secure the effect of reducing the difference in CTE between the glue layer 145 and the chip body 121.

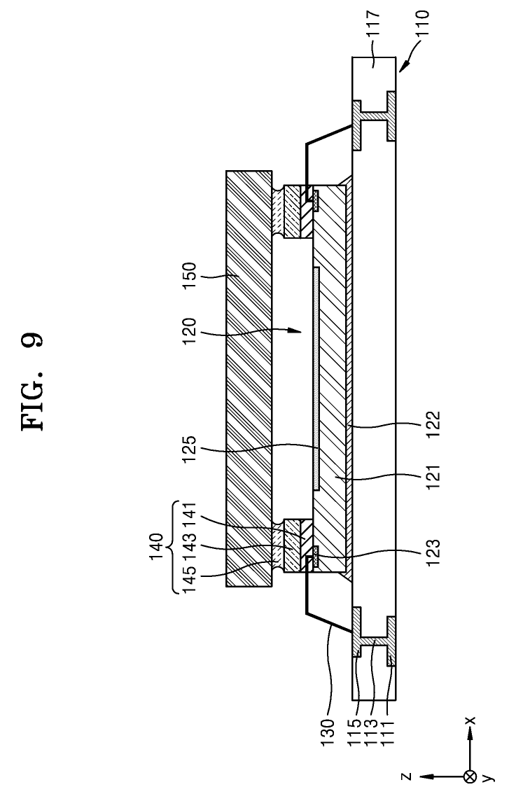

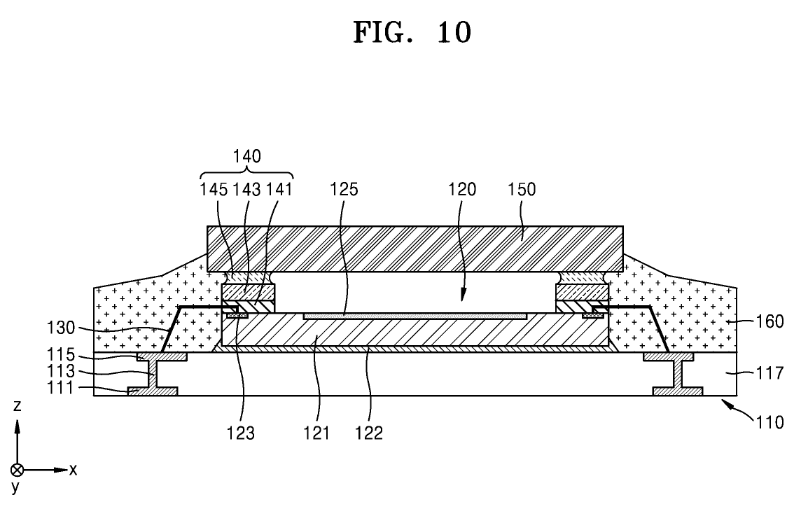

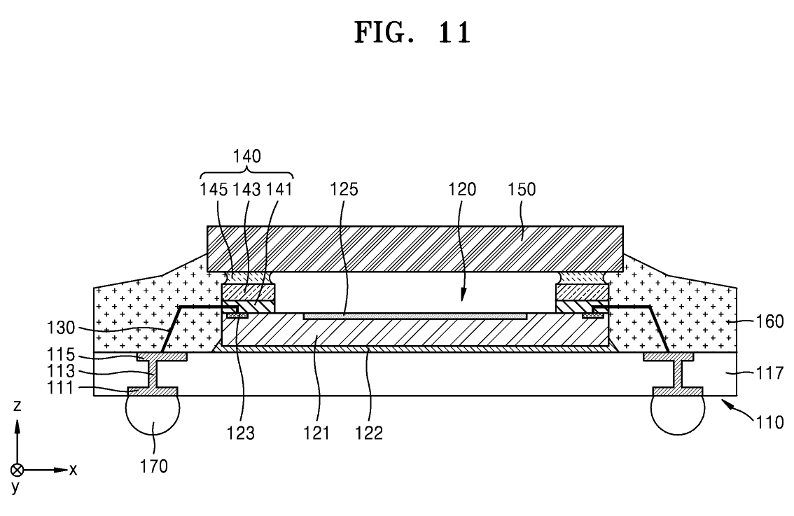

FIG. 3, FIG. 4, FIG. 5, FIG. 6, FIG. 7, FIG. 8, FIG. 9, FIG. 10 and FIG. 11 are views for describing a method of manufacturing an image sensor package 100, according to embodiments.

Referring to FIG. 3, first, the package substrate 110 including the lower substrate pads 111, the wiring layers 113, the upper substrate pads 115, and the substrate base 117 may be provided.

Referring to FIG. 4, the adhesive layer 122 may be formed by applying an adhesive onto the package substrate 110. The adhesive constituting the adhesive layer 122 may be, for example, a fluid epoxy material. The adhesive layer 122 may be formed by applying the adhesive through a dispenser and curing the adhesive to some extent. The adhesive layer 122 may be formed on the central region of the package substrate 110 to correspond to a mounting position of the image sensor chip 120 to be described below.

Referring to FIG. 5, the image sensor chip 120 may be mounted on the package substrate 110. The image sensor chip 120 is mounted on the central region of the package substrate 110 and may be attached and fixed to the package substrate 110 by the adhesive layer 122.

Referring to FIG. 6, a wire bonding process may be performed to connect the chip pads 123 of the image sensor chip 120 to the corresponding upper substrate pads 115 of the package substrate 110 by using the bonding wires 130. The wire bonding process may be performed by using, for example, a capillary. Through the wire bonding process, one end of each of the bonding wires 130 may be connected to each of the chip pads 123, and the other ends of the bonding wires 130 may be connected to the upper substrate pads 115, respectively. A material constituting the bonding wires 130 may be the same as described above.

Referring to FIG. 7, the die adhesive layer 141 having the intermediate relief layer 143 formed on the top surface of the die adhesive layer 141 may be attached onto the image sensor chip 120. Specifically, the die adhesive layer 141 in the form of a solid tape may be prepared, the intermediate relief layer 143 may be formed on the die adhesive layer 141, and then the die adhesive layer 141 having the intermediate relief layer 143 formed on the top surface of the die adhesive layer 141 may be attached onto the top surface of the image sensor chip 120. That is, in the process of manufacturing the image sensor package 100, the liquid intermediate relief layer 143 is not formed by being directly dispensed through the dispenser on the top surface of the image sensor chip 120, but after forming the intermediate relief layer 143 on the die adhesive layer 141, the die adhesive layer 141 with the intermediate relief layer 143 formed on the top surface of the die adhesive layer 141 is attached onto the top surface of the image sensor chip 120. Accordingly, the die adhesive layer 141 and the intermediate relief layer 143 may be sequentially disposed on the chip body 121 of the image sensor chip 120. Because the intermediate relief layer 143 is not formed directly on the chip body 121 through dispensing, the bleeding phenomenon of the intermediate relief layer 143, which may occur when the intermediate relief layer 143 is directly formed through dispensing, may be prevented. Therefore, it is possible to prevent the sensing region 125 of the image sensor chip 120 from being contaminated due to the bleeding of the intermediate relief layer 143.

In embodiments, the intermediate relief layer 143 may be formed on the die adhesive layer 141 such that the horizontal width of the intermediate relief layer 143 is equal to the horizontal width of the die adhesive layer 141.

The die adhesive layer 141 and the intermediate relief layer 143 may surround the outer portion of the top surface of the image sensor chip 120 and may have a rectangular ring shape. In addition, the die adhesive layer 141 may cover the chip pads 123 of the image sensor chip 120 and one end of each of the bonding wires 130 connected to the chip pads 123.

Referring to FIG. 8, the glue layer 145 may be formed on the intermediate relief layer 143. The glue layer 145 may be formed by dispensing a material such as liquid epoxy resin on the intermediate relief layer 143 by using a dispenser. As the glue layer 145 is formed on the intermediate relief layer 143, the dam structure 140 including the die adhesive layer 141, the intermediate relief layer 143, and the glue layer 145 may be formed. Because the glue layer 145 is formed by dispensing a liquid material, side surfaces 145S (refer to FIG. 2) of the glue layer 145 may have a shape of which central portion is concave inward the image sensor package.

Referring to FIG. 9, the glass cover 150 may be attached onto the dam structure 140. The glass cover 150 may be stacked on the dam structure 140 while heat and pressure are applied. The glue layer 145 of the dam structure 140 may be attached to the glass cover 150 through viscosity and may seal the cavity C1. Because the cavity C1 is sealed by the dam structure 140, external moisture or foreign substances may be prevented from flowing into the sensing region 125 of the image sensor chip 120.

Referring to FIG. 10, the sealant 160 may be applied onto the package substrate 110 to seal the image sensor chip 120, the bonding wires 130, and the glass cover 150. The sealant 160 may cover the side surfaces of the image sensor chip 120 and the external surface of the dam structure 140. In addition, the sealant 160 may cover at least parts of the side surfaces and part of the bottom surface of the glass cover 150. The sealant 160 may prevent the sensing region 125 of the image sensor chip 120 from being contaminated by external foreign substances and may protect the image sensor package 100 from external shock.

Next, in the result of FIG. 10, the image sensor package 100 illustrated in FIGS. 1 and 2 may be manufactured by attaching the external connection terminals 170 onto the lower substrate pads 111 on the bottom surface of the package substrate 110 as shown in FIG. 11. The external connection terminals 170 may be, for example, solder balls.

In embodiments, the processes of FIGS. 3 to 10 may be performed on a large-area substrate including a plurality of package substrates 110. In this case, after the external connection terminals 170 are formed, a singulation process may be performed on the large-area substrate, and after the singulation process, the image sensor package 100 illustrated in FIGS. 1 and 2 may be manufactured.

While the inventive concept has been particularly shown and described with reference to embodiments thereof, it will be understood that various changes in form and details may be made therein without departing from the spirit and scope of the following claims.

What is claimed is:

1. An image sensor package comprising:
a package substrate;
an image sensor chip disposed on a central region of the package substrate and including a chip body, a sensing region disposed in an upper central region of the chip body, and a chip pad disposed in an upper edge region of the chip body;
a bonding wire contacting the chip pad and electrically connecting the image sensor chip to the package substrate;
a dam structure disposed at an edge of the image sensor chip and overlapping the chip pad and one end of the bonding wire in contact with the chip pad in a vertical direction of the image sensor package;
a glass cover disposed on the dam structure; and
a sealant covering side surfaces of the glass cover and the bonding wire,
wherein the dam structure is disposed on the chip pad and comprises a die adhesive layer in contact with the chip pad, a glue layer in contact with the glass cover, and an intermediate relief layer disposed between the die adhesive layer and the glue layer.

2. The image sensor package of claim 1, wherein the die adhesive layer and the intermediate relief layer have the same width in a horizontal direction of the image sensor package.

3. The image sensor package of claim 1, wherein side surfaces of the die adhesive layer and side surfaces of the intermediate relief layer are disposed on the same plane in the vertical direction.

4. The image sensor package of claim 1, wherein intermediate portions of side surfaces of the glue layer are concave inward the image sensor package.

5. The image sensor package of claim 1, wherein the intermediate relief layer comprises a material reducing a difference in coefficient of thermal expansion (CTE) between the glue layer and the chip body.

6. The image sensor package of claim 1, wherein the die adhesive layer comprises a material having higher viscosity than viscosity of the intermediate relief layer.

7. The image sensor package of claim 1, wherein the die adhesive layer covers the chip pad and the one end of the bonding wire in contact with the chip pad.

8. An image sensor package comprising:
a package substrate including a substrate base, an upper substrate pad disposed on a top surface of the substrate base, a lower substrate pad disposed on a bottom surface of the substrate base and a wiring layer connecting the upper substrate pad and the lower substrate pad;
an external connection terminal disposed on the lower substrate pad;
an image sensor chip disposed on a central region of the package substrate and including a chip body, a sensing region disposed in an upper central region of the chip body, and a chip pad disposed in an upper edge region of the chip body;
a bonding wire contacting the upper substrate pad and the chip pad and electrically connecting the image sensor chip to the package substrate, wherein a first end of the bonding wire contacts the upper substrate pad;
a dam structure disposed at an edge of the image sensor chip and overlapping the chip pad and a second end of the bonding wire in contact with the chip pad in a vertical direction of the image sensor package;
a glass cover disposed on the dam structure; and
a sealant covering side surfaces of the glass cover and the bonding wire,
wherein the dam structure is disposed on the chip pad and comprises a die adhesive layer in contact with the chip pad and the second end of the bonding wire, a glue layer in contact with the glass cover, and an intermediate relief layer disposed between the die adhesive layer and the glue layer in the vertical direction.

9. The image sensor package of claim 8, wherein the intermediate relief layer comprises silicon (Si) or a metal material.

10. The image sensor package of claim 8, wherein the die adhesive layer comprises a die attach film.

11. The image sensor package of claim 8, wherein the glue layer comprises a glass attach glue.

12. The image sensor package of claim 8, wherein the die adhesive layer and the intermediate relief layer have the same width in a horizontal direction of the image sensor package.

13. The image sensor package of claim 8, wherein side surfaces of the die adhesive layer and side surfaces of the intermediate relief layer are flat surfaces disposed on the same plane in the vertical direction and intermediate portions of side surfaces of the glue layer are concave inward the image sensor package.

14. A method of manufacturing an image sensor package, the method comprising:
preparing a package substrate;
forming an adhesive layer on a central region of the package substrate and mounting an image sensor chip, which includes a chip body and a chip pad, on the adhesive layer;
forming a bonding wire connecting an upper substrate pad of the package substrate to the chip pad of the image sensor chip;
forming an intermediate relief layer on a top surface of a die adhesive layer;
attaching the die adhesive layer with the intermediate relief layer formed on a top surface of the die adhesive layer to an edge region of the image sensor chip;
forming a glue layer on the intermediate relief layer to form a dam structure;
attaching a glass cover onto the dam structure;
sealing the image sensor chip and forming a sealant covering side surfaces of the glass cover and the bonding wire; and
forming an external connection terminal on a bottom substrate pad of the package substrate.

15. The method of claim 14, wherein the edge region is a region in which the chip pad and an end of the bonding wire are disposed and the die adhesive layer is attached onto the chip pad to cover the chip pad and the end of the bonding wire in contact with the chip pad.

16. The method of claim 14, wherein the die adhesive layer comprises a solid die attach film, and the intermediate relief layer comprises a material having lower viscosity than viscosity of the die adhesive layer.

17. The method of claim 14, wherein the intermediate relief layer is formed so that a horizontal width of the intermediate relief layer is equal to a horizontal width of the die adhesive layer.

18. The method of claim 14, wherein the glue layer is formed on the intermediate relief layer by a dispensing method using a liquid material.

19. The method of claim 18, wherein the liquid material forming the glue layer includes epoxy resin.

20. The method of claim 14, wherein the intermediate relief layer comprises a material reducing a difference in coefficient of thermal expansion (CTE) between the glue layer and the chip body.
